(19) United States
(12) Patent Application Publication
(10) Pub. No.: US 2024/0365465 A1
(43) Pub. Date: Oct. 31, 2024

(54) HIGH FREQUENCY MODULE AND COMMUNICATION DEVICE

(71) Applicant: Murata Manufacturing Co., Ltd., Kyoto (JP)

(72) Inventors: Yoshihito OTSUBO, Kyoto (JP); Takuma KUROYANAGI, Kyoto (JP); Tomomi YASUDA, Kyoto (JP)

(21) Appl. No.: 18/641,621

(22) Filed: Apr. 22, 2024

(30) Foreign Application Priority Data
Apr. 28, 2023 (JP) 2023-074060

(51) Int. Cl. H05K 1/02

(52) U.S. Cl. CPC H05K 1/0243; H05K 1/0218; H05K 1/0242; H05K 2201/0715

(57) ABSTRACT

A high frequency module includes a mounting board, a first electronic component, a second electronic component, and a shield member. The mounting board has a main surface. The first electronic component and the second electronic component are disposed on the main surface of the mounting board. The shield member is disposed on the main surface of the mounting board. The shield member is positioned between the first electronic component and the second electronic component, and is adjacent to the first electronic component and the second electronic component.

### CROSS REFERENCE TO RELATED APPLICATION

This application claims priority from Japanese Patent Application No. 2023-074060 filed on Apr. 28, 2023. The content of this application is incorporated herein by reference in its entirety.

### BACKGROUND OF THE DISCLOSURE

### 1. Field of the Disclosure

The present disclosure generally relates to a high frequency module and a communication device, and more particularly relates to a high frequency module including a plurality of electronic components and a communication device including the high frequency module.

### 2. Description of the Related Art

United States Patent Application Publication No. 2017/0118875 discloses a module (high frequency module) that includes a board (a mounting board), a first electronic component and a second electronic component disposed on the board, and an internal shield (a shield member). The first electronic component is, for example, an acoustic filter. The second electronic component is, for example, a flip chip IC. The internal shield is disposed between the first electronic component and the second electronic component. The internal shield includes a pair of isolated bonding wires. The pair of isolated bonding wires are formed by removing vertices of bonding wire loops. The module disclosed in U.S. Patent Application Publication No. 2017/0118875 reduces or eliminates electromagnetic interference and strengthens the isolation between the first electronic component and the second electronic component through the internal shield.

### BRIEF SUMMARY OF THE DISCLOSURE

In the high frequency module disclosed in U.S.

Patent Application Publication No. 2017/0118875, the high frequency module may become larger due to the increase of a space required for the shield member in each of a thickness direction of the mounting board and a direction where the first electronic component and the second electronic component are arranged.

A possible benefit of the present disclosure is to provide a high frequency module and a communication device that can achieve size reduction.

A high frequency module according to an aspect of the present disclosure includes a mounting board, a first electronic component, a second electronic component, and a shield member. The mounting board has a main surface. The first electronic component and the second electronic component are disposed on the main surface of the mounting board. The shield member is disposed on the main surface of the mounting board. The shield member is positioned between the first electronic component and the second electronic component, and is adjacent to the first electronic component and the second electronic component. A first height, which is from the main surface of the mounting board to a top portion of the shield member, is lower than at least one of a second height, which is from the main surface of the mounting board to a top surface of the first electronic component, and a third height, which is from the main surface of the mounting board to a top surface of the second electronic component.

A communication device according to another aspect of the present disclosure includes the high frequency module according to the above aspect and a signal processing circuit. The signal processing circuit is connected to the high frequency module.

The high frequency module and the communication device according to the above aspect of the present disclosure can achieve size reduction.

### BRIEF DESCRIPTION OF THE SEVERAL VIEWS OF THE DRAWINGS

FIG. 1 is a cross-sectional view of a high frequency module according to Embodiment 1;

FIG. 2 is a plan view of the high frequency module same as above;

FIG. 3 is a cross-sectional view of a main portion of the high frequency module same as above;

FIG. 4 is a circuit view of a communication device including the high frequency module same as above;

FIG. 5 is a cross-sectional view of a high frequency module according to Embodiment 2;

FIG. 6 is a cross-sectional view of a high frequency module according to Embodiment 3;

FIG. 7 is a cross-sectional view of a high frequency module according to Embodiment 4;

FIG. 8 is a plan view of a high frequency module according to Embodiment 5;

FIG. 9 is a plan view of a high frequency module according to Embodiment 6;

FIG. 10 is a cross-sectional view taken along the line X1-X1 in FIG. 9, related to the high frequency module same as above;

FIG. 11 is a plan view of a high frequency module according to Embodiment 7;

FIG. 12 is a cross-sectional view taken along the line X1-X1 in FIG. 11, related to the high frequency module same as above;

FIG. 13 is a plan view of a high frequency module according to Embodiment 8;

FIG. 14 is a cross-sectional view taken along the line X1-X1 in FIG. 13, related to the high frequency module same as above;

FIG. 15 is a plan view of a high frequency module according to Embodiment 9;

FIG. 16 is a plan view of a high frequency module according to Embodiment 10;

FIG. 17 is a cross-sectional view taken along the line X1-X1 in FIG. 16, related to the high frequency module same as above;

FIG. 18 is a cross-sectional view of a high frequency module according to Embodiment 11;

FIG. 19 is a cross-sectional view of a high frequency module according to Embodiment 12;

FIG. 20 is a plan view of a high frequency module according to Embodiment 13; and

FIG. 21 is a cross-sectional view taken along the line X1-X1 in FIG. 20, related to the high frequency module same as above.

### DETAILED DESCRIPTION OF THE DISCLOSURE

Hereinafter, Embodiments 1 to 13 will be described with reference to the drawings. The drawings referred to in the following embodiment or the like are schematic drawings, the sizes and thicknesses of the components in the drawings do not necessarily reflect actual dimensions, and the ratio of the sizes and the ratio of the thicknesses between the components do not necessarily reflect the actual dimensional ratios.

### Embodiment 1

Hereinafter, a high frequency module 100 according to Embodiment 1 will be described with reference to the drawings.

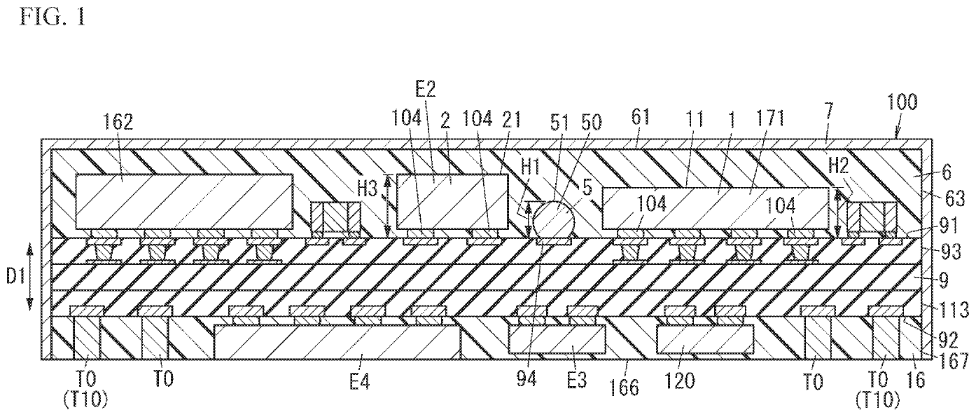

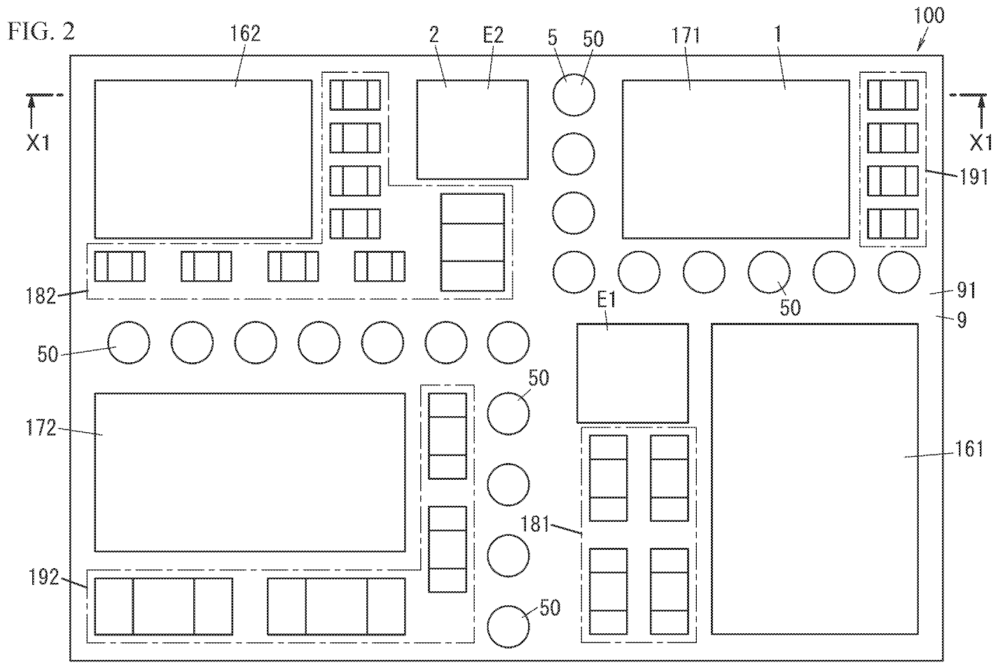

The high frequency module 100 according to Embodiment 1 includes a mounting board 9, a first electronic component 1, a second electronic component 2, and a shield member 5, as shown in FIGS. 1 and 2. The mounting board 9 has a main surface 91. The first electronic component 1 and the second electronic component 2 are disposed on the main surface 91 of the mounting board 9. The shield member 5 is disposed on the main surface 91 of the mounting board 9.

The shield member 5 is positioned between the first electronic component 1 and the second electronic component 2. The shield member 5 is adjacent to the first electronic component 1 and the second electronic component 2. The fact that “the shield member 5 is adjacent to the first electronic component 1 and the second electronic component 2” means that the shield member 5, the first electronic component 1, and the second electronic component 2 are disposed without disposing other electronic components between the shield member 5 and each of the first electronic component 1 and the second electronic component 2, in a plan view from a thickness direction D1 of the mounting board 9.

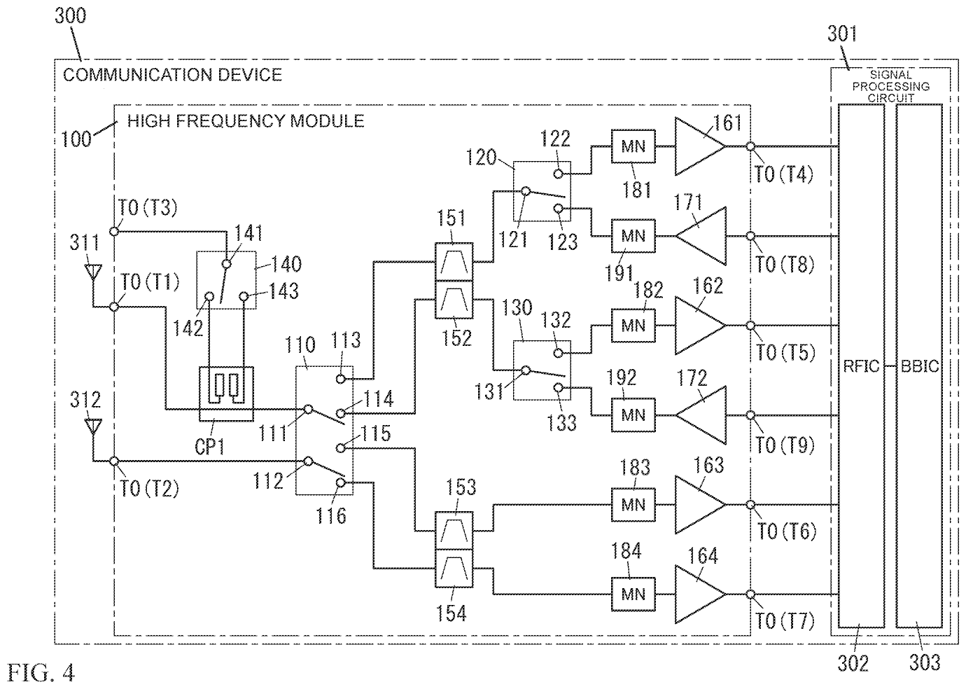

The high frequency module 100 according to Embodiment 1 is used in, for example, a communication device 300 as shown in FIG. 4. The communication device 300 is, for example, a mobile phone (for example, a smart phone), but is not limited thereto, and may be, for example, a wearable terminal (for example, a smart watch). The high frequency module 100 is, for example, a module that can support a fourth generation mobile communication (4G) standard or a fifth generation mobile communication (5G) standard. The 4G standard is, for example, a third generation partnership project (3GPP) (registered trademark) long term evolution (LTE) standard (registered trademark). The 5G standard is, for example, 5G new radio (NR). The high frequency module 100 is, for example, a module capable of supporting carrier aggregation and dual connectivity.

### 1 Circuit Configuration of High Frequency Module and Communication Device

Hereinafter, the circuit configurations of the high frequency module 100 and the communication device 300 according to Embodiment 1 will be described with reference to the drawings.

### 1.1 Circuit Configuration of High Frequency Module

As shown in FIG. 4, the high frequency module 100 includes a plurality of external connection terminals TO, a coupler CP1, a plurality of (four in the example in FIG. 4) switches 110, 120, 130, and 140, and a plurality of (four in the example in FIG. 4) filters 151 to 154. Further, the high frequency module 100 includes a plurality of (four in the example in FIG. 4) low noise amplifiers 161 to 164, a plurality of (two in the example in FIG. 4) power amplifiers 171 and 172, a plurality of (four in the example in FIG. 4) input matching circuits 181 to 184, and a plurality of (two in the example in FIG. 4) output matching circuits 191 and 192. The plurality of external connection terminals TO include a first antenna terminal T1, a second antenna terminal T2, a coupler terminal T3, a plurality of (four in the example in FIG. 4) signal output terminals T4 to T7, a plurality of (two in the example in FIG. 4) signal input terminals T8 and T9, and a plurality of ground terminals T10 (see FIG. 1).

The first antenna terminal T1 is connected to, for example, a first antenna 311 of the communication device 300.

The second antenna terminal T2 is connected to, for example, a second antenna 312 of the communication device 300.

The coupler terminal T3 is connected to, for example, a signal processing circuit 301 of the communication device 300.

The plurality of signal output terminals T4 to T7 and the plurality of signal input terminals T8 and T9 are connected to, for example, the signal processing circuit 301 of the communication device 300.

The coupler CP1 is disposed in a signal path (a main line) that connects the switch 110 and the first antenna terminal T1, detects a high frequency signal transmitted through the main line, and measures a signal strength of the high frequency signal.

The switch 110 includes two common terminals 111 and 112, and four selection terminals 113 to 116. The switch 110 switches the connection and non-connection between the common terminal 111 and at least one of the four selection terminals 113 to 116, and switches the connection and non-connection between the common terminal 112 and at least one of the four selection terminals 113 to 116. The common terminal 111 is connected to the first antenna terminal T1. The common terminal 112 is connected to the second antenna terminal T2. The selection terminal 113 is connected to the filter 151. The selection terminal 114 is connected to the filter 152. The selection terminal 115 is connected to the filter 153. The selection terminal 116 is connected to the filter 154.

The switch 120 includes a common terminal 121 and two selection terminals 122 and 123. The common terminal 121 of the switch 120 is connected to the filter 151. One selection terminal 122 of the switch 120 is connected to an input terminal of the low noise amplifier 161 with the input matching circuit 181 interposed therebetween, and the other selection terminal 123 of the switch 120 is connected to an output terminal of the power amplifier 171 with the output matching circuit 191 interposed therebetween. The switch 120 is configured with a single pole double throw (SPDT) type switch circuit.

The switch 130 includes a common terminal 131 and two selection terminals 132 and 133. The common terminal 131 of the switch 130 is connected to the filter 152. One selection terminal 132 of the switch 130 is connected to an input terminal of the low noise amplifier 162 with the input matching circuit 182 interposed therebetween, and the other selection terminal 133 of the switch 130 is connected to an output terminal of the power amplifier 172 with the output matching circuit 192 interposed therebetween. The switch 130 is configured with an SPDT type switch circuit.

The switch 140 includes a common terminal 141 and two selection terminals 142 and 143. The common terminal 141 of the switch 140 is connected to the coupler terminal T3. One selection terminal 142 of the switch 140 is connected to one sub-line included in the coupler CP1, and the other selection terminal 143 of the switch 140 is connected to the other sub-line included in the coupler CP1. That is, the switch 140 switches between the connection of the coupler terminal T3 with one sub-line and the connection of the coupler terminal T3 with the other sub-line. The switch 140 is configured with an SPDT type switch circuit.

Each of the plurality of filters 151 to 154 includes an acoustic wave filter. The acoustic wave filter includes a plurality of acoustic wave resonators. Each of the plurality of acoustic wave resonators is a surface acoustic wave (SAW) resonator. The filter 151 is a transmission and reception filter that passes a transmission signal and a reception signal in a first communication band. The filter 152 is a transmission and reception filter that passes a transmission signal and a reception signal in a second communication band. The filter 153 is a reception filter that passes a reception signal in a third communication band. The filter 154 is a reception filter that passes a reception signal in a fourth communication band.

Each of the plurality of low noise amplifiers 161 to 164 includes an input terminal and an output terminal. The low noise amplifier 161 amplifies the reception signal in the first communication band, which is inputted from the input terminal, with low noise and outputs the reception signal from the output terminal. The input terminal of the low noise amplifier 161 is connected to the filter 151 with the input matching circuit 181 and the switch 120 interposed therebetween, and the output terminal of the low noise amplifier 161 is connected to the signal output terminal T4. The low noise amplifier 162 amplifies the reception signal in the second communication band, which is inputted from the input terminal, with low noise and outputs the reception signal from the output terminal. The input terminal of the low noise amplifier 162 is connected to the filter 152 with the input matching circuit 182 and the switch 130 interposed therebetween, and the output terminal of the low noise amplifier 162 is connected to the signal output terminal T5. The low noise amplifier 163 amplifies the reception signal in the third communication band, which is inputted to the input terminal, with low noise and outputs the reception signal from the output terminal. The input terminal of the low noise amplifier 163 is connected to the filter 153 with the input matching circuit 183 interposed therebetween, and the output terminal of the low noise amplifier 163 is connected to the signal output terminal T6. The low noise amplifier 164 amplifies the reception signal in the fourth communication band, which is inputted to the input terminal, with low noise and outputs the reception signal from the output terminal. The input terminal of the low noise amplifier 164 is connected to the filter 154 with the input matching circuit 184 interposed therebetween, and the output terminal of the low noise amplifier 164 is connected to the signal output terminal T7.

Each of the plurality of power amplifiers 171 and 172 includes an input terminal and an output terminal. The power amplifier 171 amplifies the transmission signal in the first communication band, which is inputted to the input terminal, and outputs the transmission signal from the output terminal. The input terminal of the power amplifier 171 is connected to the signal input terminal T8, and the output terminal of the power amplifier 171 is connected to the filter 151 with the output matching circuit 191 and the switch 120 interposed therebetween. The input terminal of the power amplifier 172 is connected to the signal input terminal T9, and the output terminal of the power amplifier 172 is connected to the filter 152 with the output matching circuit 192 and the switch 130 interposed therebetween.

The input matching circuit 181 is connected between the switch 120 and the low noise amplifier 161, and matches the impedances of the switch 120 and the low noise amplifier 161. The input matching circuit 182 is connected between the switch 130 and the low noise amplifier 162, and matches the impedances of the switch 130 and the low noise amplifier 162. The input matching circuit 183 is connected between the filter 153 and the low noise amplifier 163, and matches the impedances of the filter 153 and the low noise amplifier 163. The input matching circuit 184 is connected between the filter 154 and the low noise amplifier 164, and matches the impedances of the filter 154 and the low noise amplifier 164.

The output matching circuit 191 is connected between the power amplifier 171 and the switch 120, and matches the impedances of the power amplifier 171 and the switch 120. The output matching circuit 192 is connected between the power amplifier 172 and the switch 130, and matches the impedances of the power amplifier 172 and the switch 130.

### 1.2 Circuit Configuration of Communication Device

As shown in FIG. 4, the communication device 300 includes the high frequency module 100, the signal processing circuit 301, the first antenna 311, and the second antenna 312.

The signal processing circuit 301 includes an RF signal processing circuit 302 and a baseband signal processing circuit 303. The RF signal processing circuit 302 is, for example, a radio frequency integrated circuit (RFIC) and performs signal processing on a high frequency signal. The RF signal processing circuit 302, for example, performs signal processing, such as upconverting, on a high frequency signal (transmission signal) outputted from the baseband signal processing circuit 303, and outputs the high frequency signal on which the signal processing is performed. Further, the RF signal processing circuit 302, for example, performs signal processing, such as downconversion, on a high frequency signal (reception signal) outputted from the high frequency system 200, and outputs the high frequency signal on which the signal processing is performed to the baseband signal processing circuit 303. The baseband signal processing circuit 303 is, for example, a baseband integrated circuit (BBIC). The baseband signal processing circuit 303 generates an I phase signal and a Q phase signal from the baseband signal. The baseband signal is, for example, an audio signal or an image signal inputted from the outside. The baseband signal processing circuit 303 performs IQ modulation processing by combining the I phase signal and the Q phase signal, and outputs a transmission signal. At this time, the transmission signal is generated as a modulation signal (IQ signal) in which a carrier wave signal of a predetermined frequency is amplitude-modulated in a period longer than a period of the carrier wave signal. The reception signal processed by the baseband signal processing circuit 303 is used, for example, as an image signal for image display or as an audio signal for a call by the user of the communication device 300.

### 2 Structure of High Frequency Module

As shown in FIGS. 1 and 2, the high frequency module 100 according to Embodiment 1 includes the mounting board 9 and the plurality of electronic components. The plurality of electronic components include the low noise amplifier 161, the low noise amplifier 162, the power amplifier 171, the power amplifier 172, the switch 120, an electronic component E1, an electronic component E2, an electronic component E3, and an electronic component E4. The electronic component E1 includes the filter 151 and the filter 152. The electronic component E2 includes the filter 153 and the filter 154. The electronic component E3 includes the coupler CP1 and the switch 140. The electronic component E4 includes the switch 110, the switch 130, the low noise amplifier 163, and the low noise amplifier 164. Further, the plurality of electronic components include a plurality of circuit elements included in the input matching circuit 181, a plurality of circuit elements included in the input matching circuit 182, a plurality of circuit elements included in the output matching circuit 191, and a plurality of circuit elements included in the output matching circuit 192. Among the plurality of electronic components, each of the power amplifier 171, the power amplifier 172, the plurality of circuit elements included in the output matching circuit 191, and the plurality of circuit elements included in the output matching circuit 192 are transmission electronic components. Among the plurality of electronic components, each of the low noise amplifier 161, the low noise amplifier 162, the electronic component E2, the plurality of circuit elements included in the input matching circuit 181, and the plurality of circuit elements included in the input matching circuit 182 are reception electronic components.

Further, the high frequency module 100 includes a plurality of external connection terminals TO.

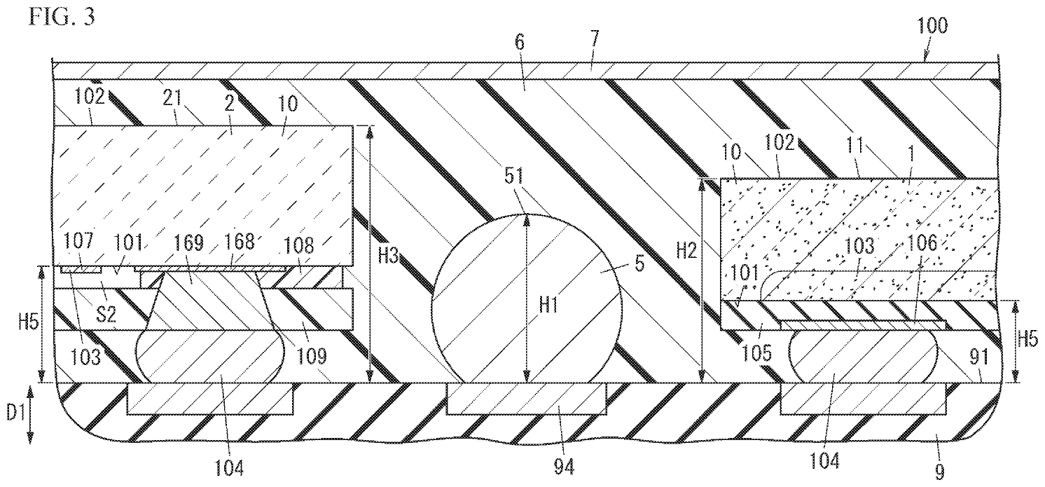

Further, the high frequency module 100 includes a plurality of (20 in the example in FIG. 2) solder bumps 50. Each of the plurality of solder bumps 50 is adjacent to at least one electronic component among the plurality of electronic components. The fact that “each of the plurality of solder bumps 50 is adjacent to at least one electronic component among the plurality of electronic components” means that the solder bump 50 and the at least one electronic component are disposed without disposing other electronic components between the solder bump 50 and the at least one electronic component, in a plan view from the thickness direction D1 of the mounting board 9. In the high frequency module 100, the power amplifier 171 is an example of a first electronic component 1, and the electronic component E2 is an example of a second electronic component 2. Further, in the high frequency module 100, a solder bump 50, which is positioned between the first electronic component 1 and the second electronic component 2 among the plurality of solder bumps 50, is an example of the shield member 5. In the example in FIG. 2, nine solder bumps 50 among the 20 solder bumps 50 are disposed to be arranged along two adjacent sides among four sides included in an outer edge of the first electronic component 1. Further, in the example in FIG. 2, the remaining eleven solder bumps 50 among the twenty solder bumps 50 are disposed to be arranged along two adjacent sides among four sides included in an outer edge of the power amplifier 172. Each of the first electronic component 1 and the second electronic component 2 includes a board 10 as shown in FIG. 3. The board 10 has a first main surface 101 and a second main surface 102, which are opposite to each other in the thickness direction of the board 10.

Further, the high frequency module 100 according to Embodiment 1 further includes a resin layer 6 (hereinafter, also referred to as a first resin layer 6), a second resin layer 16, and an outer shield electrode 7. FIG. 1 is a cross-sectional view taken along the line X1-X1 in FIG. 2. In FIG. 2, the first resin layer 6 and the outer shield electrode 7 are not shown.

As shown in FIG. 1, the mounting board 9 has the main surface 91 (hereinafter, also referred to as a third main surface 91) and a fourth main surface 92, which are opposite to each other in the thickness direction D1 of the mounting board 9. In plan view from the thickness direction D1 of the mounting board 9, although an outer edge of the mounting board 9 has, for example, a rectangular shape, the outer edge may have a shape other than a rectangular shape. The mounting board 9 is, for example, a multilayer board in which a plurality of dielectric layers and a plurality of conductive layers (not shown) are laminated. The plurality of conductive layers are formed in a predetermined pattern determined for each layer. Each of the plurality of conductive layers includes one or a plurality of conductor portions in one plane orthogonal to the thickness direction D1 of the mounting board 9. A material of each conductive layer is, for example, copper. The plurality of conductive layers include a ground layer. A ground layer of the mounting board 9 is electrically connected to at least one ground terminal included in the plurality of external connection terminals TO with a via conductor or the like, which is included in the mounting board 9, interposed therebetween.

The mounting board 9 is, for example, a low temperature co-fired ceramics (LTCC) board. The mounting board 9 is not limited to the LTCC board, and may be, for example, a printed wiring board, a high temperature co-fired ceramics (HTCC) board, a resin multilayer board, or a component built-in board.

In the high frequency module 100, the plurality of electronic components are disposed on the third main surface 91 or the fourth main surface 92 of the mounting board 9. The fact that “the electronic component is disposed on the third main surface 91 of the mounting board 9” includes the fact that the electronic component is mounted on (mechanically connected to) the third main surface 91 of the mounting board 9 and the fact that the electronic component is electrically connected to (an appropriate conductor portion of) the mounting board 9. The fact that “the electronic component is disposed on the fourth main surface 92 of the mounting board 9” includes the fact that the electronic component is mounted on (mechanically connected to) the fourth main surface 92 of the mounting board 9 and the fact that the electronic component is electrically connected to (an appropriate conductor portion of) the mounting board 9. In the high frequency module 100, the first electronic component 1 and the second electronic component 2 are disposed on the third main surface 91 of the mounting board 9.

In a plan view from the thickness direction D1 of the mounting board 9, an outer edge of each of the plurality of electronic components has, for example, a rectangular shape.

Each of the low noise amplifier 161 and the low noise amplifier 162 is a Si-based IC chip.

The power amplifier 171 is a power amplification IC chip. The power amplifier 171 is, for example, a GaAs IC chip when an amplification transistor included in the power amplifier 171 is a bipolar transistor. Further, the power amplifier 171 is, for example, a Si-based IC chip when the amplification transistor is a field effect transistor (FET). As described above, the power amplifier 171 is an example of the first electronic component 1.

The power amplifier 172 is a power amplification IC chip. The power amplifier 172 is, for example, a GaAs IC chip when the amplification transistor included in the power amplifier 172 is a bipolar transistor. Further, the power amplifier 172 is, for example, a Si-based IC chip when the amplification transistor is an FET.

Each of the plurality of circuit elements included in the output matching circuit 191 is a surface mount electronic component. A part of circuit elements among the plurality of circuit elements of the output matching circuit 191 may be built in the mounting board 9.

Each of the plurality of circuit elements included in the output matching circuit 192 is a surface mount electronic component. A part of circuit elements among the plurality of circuit elements of the output matching circuit 192 may be built in the mounting board 9.

The plurality of external connection terminals TO are disposed on the fourth main surface 92 of the mounting board 9. Materials of the plurality of external connection terminals TO are, for example, metal (for example, copper, copper alloy, or the like). Each of the plurality of external connection terminals TO is a columnar-shaped electrode (for example, a cylindrical-shaped electrode).

As shown in FIG. 1, the first resin layer 6 is disposed on the third main surface 91 of the mounting board 9 and covers a part of the plurality of electronic components, the plurality of solder bumps 50, and the third main surface 91 of the mounting board 9. The first resin layer 6 has electric insulation. The first resin layer 6 includes a resin (for example, epoxy resin). The first resin layer 6 may include a filler in addition to a resin.

The second resin layer 16 is disposed on the fourth main surface 92 of the mounting board 9. The second resin layer 16 covers an outer peripheral surface and a top surface of the electronic component E3 disposed on the fourth main surface 92 of the mounting board 9, an outer peripheral surface of the electronic component E4, and each of an outer peripheral surface of the switch 120 and plurality of external connection terminals TO. The second resin layer 16 does not cover the main surface of the electronic component E4 opposite to the mounting board 9 side. The second resin layer has electric insulation. The second resin layer 16 includes a resin (for example, epoxy resin). The second resin layer 16 may include a filler in addition to a resin. The material of the second resin layer 16 may be the same material as the material of the first resin layer 6, or may be a different material.

The outer shield electrode 7 covers the first resin layer 6 and the mounting board 9. More specifically, the outer shield electrode 7 covers a main surface 61 and an outer peripheral surface 63 of the first resin layer 6, an outer peripheral surface 93 of the mounting board 9, and an outer peripheral surface 167 of the second resin layer 16. In the high frequency module 100, a main surface 166 of the second resin layer 16 opposite to the mounting board 9 side is not covered with the outer shield electrode 7 and is exposed.

The outer shield electrode 7 has conductivity. In the high frequency module 100, the outer shield electrode 7 is a shield layer provided for the purpose of electromagnetic shielding inside and outside the high frequency module 100. The outer shield electrode 7 is in contact with at least a part of an outer peripheral surface of the ground layer included in the mounting board 9. Accordingly, the potential of the outer shield electrode 7 can be set to be the same as the potential of the ground layer. Although the outer shield electrode 7 has a multilayer structure in which a plurality of metal layers are laminated, the outer shield electrode 7 is not limited to a multilayer structure and may have one metal layer. The metal layer includes one or a plurality of metals.

### 3 Structures of First Electronic Component and Second Electronic Component

As shown in FIG. 3, each of the first electronic component 1 and the second electronic component 2 includes the board 10, a circuit portion 103, and a plurality of bump electrodes 104 (in FIG. 3, only one of the plurality of bump electrodes 104 is visible). The board 10 has the first main surface 101 and the second main surface 102, which are opposite to each other in the thickness direction of the board 10. The circuit portion 103 is formed on the first main surface 101 of the board 10. The plurality of bump electrodes 104 are connected to the circuit portion 103. In the first electronic component 1, the second main surface 102 of the board 10 included in the first electronic component 1 configures a top surface 11 of the first electronic component 1. Further, in the second electronic component 2, the second main surface 102 of the board 10 included in the second electronic component 2 configures a top surface 21 of the second electronic component 2.

The first electronic component 1 and the second electronic component 2 are connected to the mounting board 9 through the plurality of bump electrodes 104.

When the first electronic component 1 is an IC chip (for example, the power amplifier 171), the board 10 includes, for example, a silicon board, a GaAs board, or a silicon on insulator (SOI) board. Further, when the first electronic component 1 is an IC chip, the first electronic component 1 includes an insulation layer 105 and a plurality of pad electrodes 106. The insulation layer 105 is formed on the first main surface 101 of the board 10. The insulation layer 105 includes, for example, an interlayer insulation film and a passivation film. The circuit portion 103 is formed across a region on the first main surface 101 side among the first main surface 101 and the second main surface 102 in the board 10, and the insulation layer 105. When the first electronic component 1 is the power amplifier 171, the circuit portion 103 includes a plurality of transistors. The plurality of pad electrodes 106 are connected to the circuit portion 103. The IC chip configuring the first electronic component 1 is connected to the mounting board 9 through, for example, the plurality of bump electrodes 104 connected to the plurality of pad electrodes 106 in a one-to-one manner. The material of each bump electrode 104 is, for example, solder.

When the second electronic component 2 is an electronic component (the electronic component E2 in an example) that includes an acoustic wave filter, the board 10 includes, for example, a piezoelectric-type board. The piezoelectric-type board is, for example, a piezoelectric substrate. The piezoelectric substrate is, for example, a lithium tantalate board or a lithium niobate board. The piezoelectric-type board is not limited to a piezoelectric substrate and may be, for example, a laminated board including a piezoelectric body layer. The laminated board includes, for example, a silicon board, a silicon nitride film on the silicon board, a silicon oxide film on the silicon nitride film, and a piezoelectric body layer on the silicon oxide film. The material of the piezoelectric body layer is, for example, a lithium tantalate or lithium niobate board. Further, the circuit portion 103 includes a plurality of IDT electrodes 107 formed on the first main surface 101 of the board 10 and a plurality of wiring portions 168 formed on the first main surface 101 of the board 10. In FIG. 3, only one IDT electrode 107 among the plurality of IDT electrodes 107 is visible. Further, in FIG. 3, only one wiring portion 168 among the plurality of wiring portions 168 is visible. Further, the electronic component E2 includes a spacer layer 108, a cover member 109, and a plurality of through electrodes 169. In FIG. 3, only one through electrode 169 among the plurality of through electrodes 169 is visible. The electronic component E2 configuring the second electronic component 2 is connected to the mounting board 9 through the plurality of bump electrodes 104 connected to the plurality of through electrodes 169 in a one-to-one manner. The material of each bump electrode 104 is, for example, solder.

The spacer layer 108 is formed on the first main surface 101 of the board 10. The spacer layer 108 is formed along the outer edge of the board 10 in a plan view. The spacer layer 108 has a rectangular frame shape in a plan view from the thickness direction of the board 10. The spacer layer 108 surrounds the plurality of IDT electrodes 107, in a plan view in a thickness direction of the board 10. The spacer layer 108 has electric insulation. The material of the spacer layer 108 is an epoxy resin, a polyimide, or the like.

The cover member 109 has a flat plate shape. The cover member 109 is disposed on the spacer layer 108 to face the board 10 in the thickness direction of the board 10. The cover member 109 overlaps the plurality of IDT electrodes 107 in the thickness direction of the board 10 and is separated from the plurality of IDT electrodes 107 in the thickness direction of the board 10. The cover member 109 has electric insulation. The material of the cover member 109 is an epoxy resin, a polyimide, or the like. The electronic component E2 has a space S2 surrounded by the first main surface 101 of the board 10, the spacer layer 108, and the cover member 109. The space S2 contains gas. The gas is air, inert gas (for example, nitrogen gas), or the like.

### 4 Relationship Between First Electronic Component, Second Electronic Component, and Shield Member

The first electronic component 1, the second electronic component 2, and the shield member 5 are disposed on the main surface 91 of the mounting board 9. The shield member 5 is positioned between the first electronic component 1 and the second electronic component 2. Further, the shield member 5 is adjacent to the first electronic component 1 and the second electronic component 2. The fact that “the shield member 5 is positioned between the first electronic component 1 and the second electronic component 2” means that at least one line segment from a group of line segments connecting any point of the first electronic component 1 and any point of the second electronic component 2 passes through the shield member 5, in a plan view from the thickness direction D1 of the mounting board 9. The fact that “the shield member 5 is adjacent to the first electronic component 1 and the second electronic component 2” means that the shield member 5, the first electronic component 1, and the second electronic component 2 are disposed without disposing other electronic components between the shield member 5 and the first electronic component 1, and without disposing other electronic components between the shield member 5 and the second electronic component 2. The shield member 5 is connected to, for example, the ground layer included in the mounting board 9. The shield member 5 has a function of reducing the influence of electromagnetic noise from the first electronic component 1 to the second electronic component 2 and the influence of electromagnetic noise from the second electronic component 2 to the first electronic component 1. Further, the shield member 5 has a function of reducing the influence of electromagnetic noise from the outside of the high frequency module 100.

In the high frequency module 100, the shield member 5 has a substantially spherical shape. The shield member 5 has a circular shape in a plan view from the thickness direction D1 of the mounting board 9. In the high frequency module 100, when the first electronic component 1 is the power amplifier 171 and the second electronic component 2 is the electronic component E2, a first height H1, which is from the main surface 91 of the mounting board 9 to a top portion 51 of the shield member 5, is lower than a second height H2, which is from the main surface 91 of the mounting board 9 to the top surface 11 of the first electronic component 1. Further, in the high frequency module 100, the height H1, which is from the main surface 91 of the mounting board 9 to the top portion 51 of the shield member 5, is lower than a third height H3, which is from the main surface 91 of the mounting board 9 to the top surface 21 of the second electronic component 2. The top portion 51 of the shield member 5 is a portion of a surface of the shield member 5 farthest from the main surface 91 of the mounting board 9 in the thickness direction D1 of the mounting board 9.

Further, in the high frequency module 100, as shown in FIG. 3, the first height H1 is higher than a height H5, which is from the main surface 91 of the mounting board 9 to the first main surface 101 of the board 10 of the first electronic component 1. Further, the first height H1 is higher than the height H5, which is from the main surface 91 of the mounting board 9 to the first main surface 101 of the board 10 of the second electronic component 2.

Further, in the high frequency module 100, two shield members 5 are disposed between the first electronic component 1 and the second electronic component 2. That is, the high frequency module 100 includes two shield members 5. In the high frequency module 100, the mounting board 9 includes two land electrodes 94 corresponding to the two shield members 5 in a one-to-one manner. Each of the two shield members 5 is disposed on the corresponding land electrode 94 among the two land electrodes 94.

In the high frequency module 100, the first height H1 may be higher than at least one of the second height H2 and the third height H3.

Further, a combination of the first electronic component 1 and the second electronic component 2 is not limited to a combination of the power amplifier 171 and the electronic component E2. The combination of the first electronic component 1 and the second electronic component 2 may be, for example, a combination of the power amplifier 171 and the electronic component E1 or a combination of the power amplifier 171 and the low noise amplifier 161, and in any combination, the solder bumps 50 positioned between the first electronic component 1 and the second electronic component 2 configures the shield member 5.

### 5 Effects

The high frequency module 100 according to Embodiment 1 includes the mounting board 9, the first electronic component 1, the second electronic component 2, and the shield member 5. The mounting board 9 has the main surface 91. The first electronic component 1 and the second electronic component 2 are disposed on the main surface 91 of the mounting board 9. The shield member 5 is disposed on the main surface 91 of the mounting board 9. The shield member 5 is positioned between the first electronic component 1 and the second electronic component 2. The shield member 5 is adjacent to the first electronic component 1 and the second electronic component 2. The first height H1, which is from the main surface 91 of the mounting board 9 to the top portion 51 of the shield member 5, is lower than at least one of the second height H2, which is from the main surface 91 of the mounting board 9 to the top surface 11 of the first electronic component 1, and the third height H3, which is from the main surface 91 of the mounting board 9 to the top surface 21 of the second electronic component 2.

According to the above configuration, it is possible to achieve size reduction. In the high frequency module 100 according to Embodiment 1, since the first height H1 is lower than at least one of the second height H2 and the third height H3, it is possible to achieve size reduction while adopting a configuration in which the shield member 5 is disposed between the first electronic component 1 and the second electronic component 2.

Further, in the high frequency module 100, the first height H1 is lower than both the second height H2 and the third height H3.

According to the above configuration, it is possible to achieve further size reduction.

Further, in the high frequency module 100, the first height H1 is higher than the height H5, which is from the main surface 91 of the mounting board 9 to the first main surface 101 of the board 10 of each of the first electronic component 1 and the second electronic component 2.

With the above configuration, a magnetic field generated in the circuit portion 103 of at least one of the first electronic component 1 and the second electronic component 2 can be blocked by the shield member 5, and it is possible to achieve size reduction while improving the isolation between the circuit portion 103 of the first electronic component 1 and the circuit portion 103 of the second electronic component 2.

Further, in the high frequency module 100, the first electronic component 1 is a transmission electronic component, and the second electronic component 2 is a reception electronic component.

According to the above configuration, it is possible to achieve size reduction while improving the isolation between the transmission electronic component, which is the first electronic component 1, and the reception electronic component, which is the second electronic component 2.

In FIG. 3, although the land electrode 94 has a structure that is embedded inside the mounting board 9, the land electrode 94 may be disposed on the main surface 91 of the mounting board 9. Even with such a configuration, since the first height H1, the second height H2, and the third height H3 are heights with the main surface 91 of the mounting board 9 as a reference, the first height H1 to the third height H3 have values in which the thickness of the land electrode 94 in the thickness direction D1 of the mounting board 9 is added.

### Embodiment 2

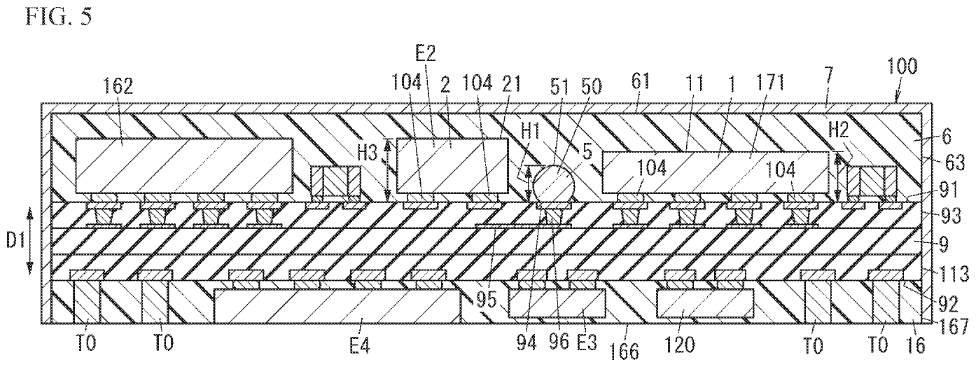

A high frequency module 100 according to Embodiment 2 will be described with reference to FIG. 5. Regarding the high frequency module 100 according to Embodiment 2, the same components as the high frequency module 100 (see FIGS. 1 to 4) according to Embodiment 1 are attached with the same reference numerals, and the description thereof will be omitted.

As shown in FIG. 5, the high frequency module 100 according to Embodiment 2 is different from the high frequency module 100 according to Embodiment 1 in a fact that a part of the ground electrode 95 included in the mounting board 9 is disposed to overlap with the shield member 5 in the thickness direction D1 of the mounting board 9. The shield member 5 and the ground electrode 95 are connected through a via conductor 96 that overlaps the shield member 5 in the thickness direction D1 of the mounting board 9.

As with the high frequency module 100 according to Embodiment 1, since the high frequency module 100 according to Embodiment 2 has the first height H1 lower than at least one of the second height H2 and the third height H3, it is possible to achieve size reduction.

Further, in the high frequency module 100 according to Embodiment 2, the ground electrode 95 of the mounting board 9 is spaced apart from the land electrode 94 and the fourth main surface 92, between the land electrode 94 and the fourth main surface 92 in the thickness direction D1 of the mounting board 9. The via conductor 96 connects the land electrode 94 and the ground electrode 95.

According to the above configuration, it is possible to suppress the expansion of the magnetic field generated by at least one of the first electronic component 1 and the second electronic component 2 in the mounting board 9.

### Embodiment 3

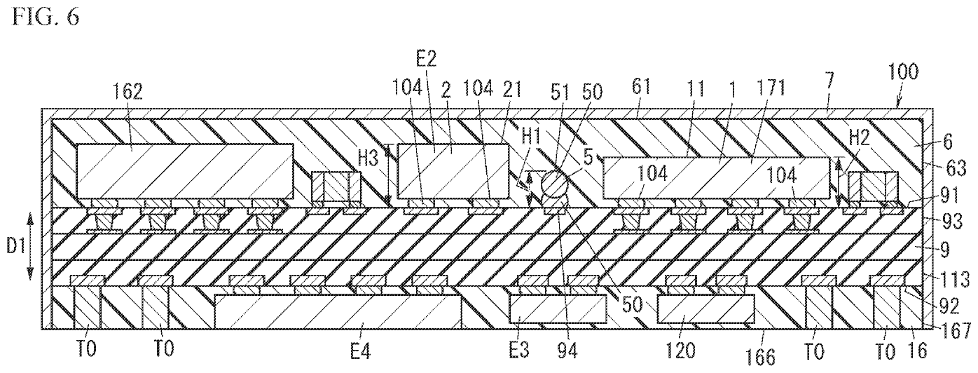

A high frequency module 100 according to Embodiment 3 will be described with reference to FIG. 6. Regarding the high frequency module 100 according to Embodiment 3, the same components as the high frequency module 100 (see FIGS. 1 to 4) according to Embodiment 1 are attached with the same reference numerals, and the description thereof will be omitted.

In the high frequency module 100 according to Embodiment 3, a shape of the shield member 5 is different from the shape of the shield member 5 of the high frequency module 100 according to Embodiment 1. In the high frequency module 100 according to Embodiment 3, the shield member 5 includes two solder bumps 50 stacked in the thickness direction D1 of the mounting board 9.

As with the high frequency module 100 according to Embodiment 1, since the high frequency module 100 according to Embodiment 3 has the first height H1 lower than at least one of the second height H2 and the third height H3, it is possible to achieve size reduction.

In the high frequency module 100 according to Embodiment 3, since the two solder bumps 50 are stacked on the shield member 5, the size of the solder bumps 50 can be made smaller as compared with Embodiment 1, and each of a distance between the shield member 5 and the first electronic component 1 and a distance between the shield member 5 and the second electronic component 2 can be shortened, and then it is possible to achieve further size reduction.

### Embodiment 4

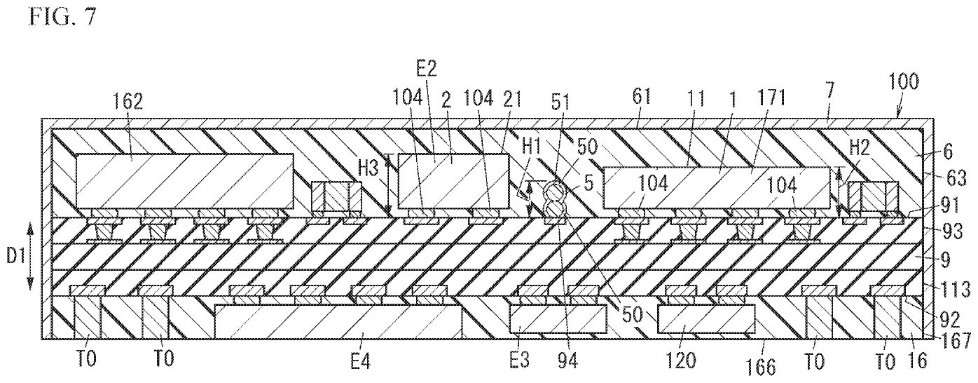

A high frequency module 100 according to Embodiment 4 will be described with reference to FIG. 7. Regarding the high frequency module 100 according to Embodiment 4, the same components as the high frequency module 100 (see FIG. 6) according to Embodiment 3 are attached with the same reference numerals, and the description thereof will be omitted.

The high frequency module 100 according to Embodiment 4 is different from the high frequency module 100 according to Embodiment 3 in a fact that each of the two solder bumps 50 included in the shield member 5 is configured with a solder bump having a copper core.

As with the high frequency module 100 according to Embodiment 3, since the high frequency module 100 according to Embodiment 4 has the first height H1 lower than at least one of the second height H2 and the third height H3, it is possible to achieve size reduction.

Further, in the high frequency module 100 according to Embodiment 4, since each of the two solder bumps 50 included in the shield member 5 is configured with a solder bump having a copper core, it is possible to improve the accuracy of the first height H1, which is from the main surface 91 of the mounting board 9 to the top portion 51 of the shield member 5 as compared with Embodiment 3.

### Embodiment 5

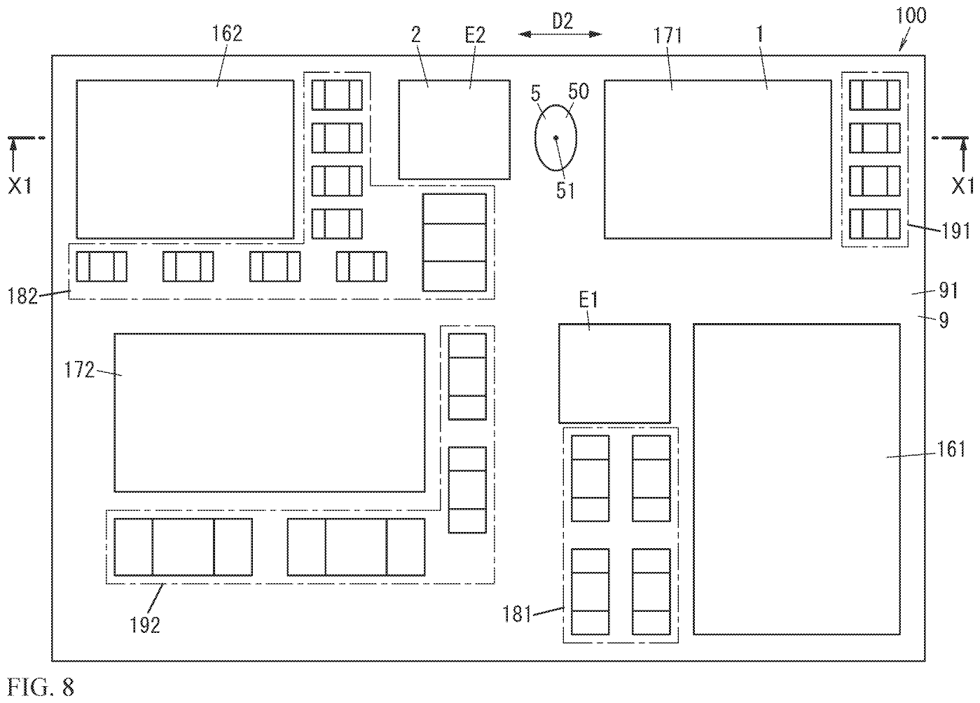

A high frequency module 100 according to Embodiment 5 will be described with reference to FIG. 8. Regarding the high frequency module 100 according to Embodiment 5, the same components as the high frequency module 100 (see FIGS. 1 to 4) according to Embodiment 1 are attached with the same reference numerals, and the description thereof will be omitted. In FIG. 8, the first resin layer 6 (see FIG. 1) and the outer shield electrode 7 (see FIG. 1) are not shown.

In the high frequency module 100 according to Embodiment 5, the first electronic component 1 and the second electronic component 2 are arranged in a second direction D2 orthogonal to the thickness direction D1 (hereinafter, also referred to as a first direction D1) of the mounting board 9. The high frequency module 100 according to Embodiment 5 is different from the high frequency module 100 according to Embodiment 1 in a fact that the shape of the shield member 5 is an elliptical shape in a plan view from the thickness direction D1 of the mounting board 9. The shield member 5 is disposed such that the short axis having an elliptical shape is parallel to the second direction D2 and the long axis having an elliptical shape is orthogonal to the second direction D2. The fact that “the short axis having an elliptical shape parallel to the second direction D2” is not limited to a case of being strictly parallel, and the angle between the short axis having an elliptical shape and the second direction D2 may be equal to or less than 10 degrees. The fact that “the long axis having an elliptical shape is orthogonal to the second direction D2” is not limited to a case of being strictly orthogonal, and the angle between the long axis having an elliptical shape and the second direction D2 may be equal to or greater than 80 degrees and equal to or less than 100 degrees.

As with the high frequency module 100 according to Embodiment 1, since the high frequency module 100 according to Embodiment 5 has the first height H1 lower than at least one of the second height H2 and the third height H3, it is possible to achieve size reduction.

Further, in the high frequency module 100 according to Embodiment 5, since the plan view shape of the shield member 5 is an elliptical shape, it is possible to improve the shielding performance by using one shield member 5, as compared with the high frequency module 100 according to Embodiment 1.

### Embodiment 6

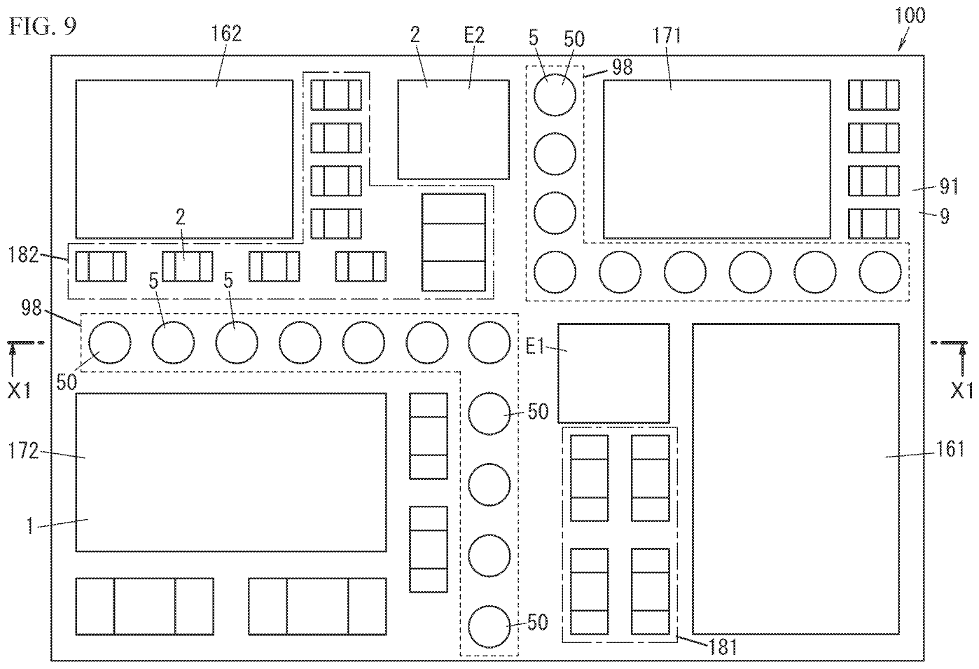

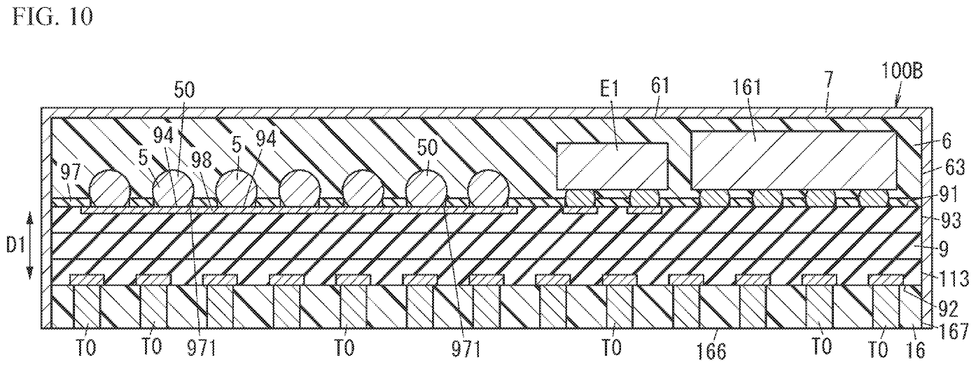

A high frequency module 100 according to Embodiment 6 will be described with reference to FIGS. 9 and 10.

Regarding the high frequency module 100 according to Embodiment 6, the same components as the high frequency module 100 (see FIG. 5) according to Embodiment 2 are attached with the same reference numerals, and the description thereof will be omitted. In FIG. 9, the first resin layer 6 (see FIG. 10) and the outer shield electrode 7 (see FIG. 10) are not shown.

In the high frequency module 100 according to Embodiment 6, as shown in FIGS. 9 and 10, the mounting board 9 includes two conductor portions 98 and a resist layer 97.

The conductor portion 98 includes at least two land electrodes 94 among the plurality of land electrodes 94. The resist layer 97 is provided on the conductor portion 98 and includes at least two cavities 971. The resist layer 97 is, for example, a solder resist layer. The material of the resist layer 97 is a material having lower solder wettability than that of the conductor portion 98. As the material of the resist layer 97, for example, a polyimide resin, an epoxy resin, or the like can be used.

The at least two land electrodes 94 are portions that correspond to at least two cavities 971 in a one-to-one manner and that are exposed through the at least two cavities 971 in the conductor portion 98. The via conductor 96 is common to the at least two land electrodes 94 and connects the conductor portion 98 and the ground electrode 95.

As with the high frequency module 100 according to Embodiment 2, since the high frequency module 100 according to Embodiment 6 has the first height H1 lower than at least one of the second height H2 and the third height H3, it is possible to achieve size reduction.

Further, in the high frequency module 100 according to Embodiment 6, since the via conductor 96 is common to at least two land electrodes 94 and connects the conductor portion 98 and the ground electrode 95, the degree of freedom in wiring layout in the mounting board 9 is increased while improving shielding performance.

### Embodiment 7

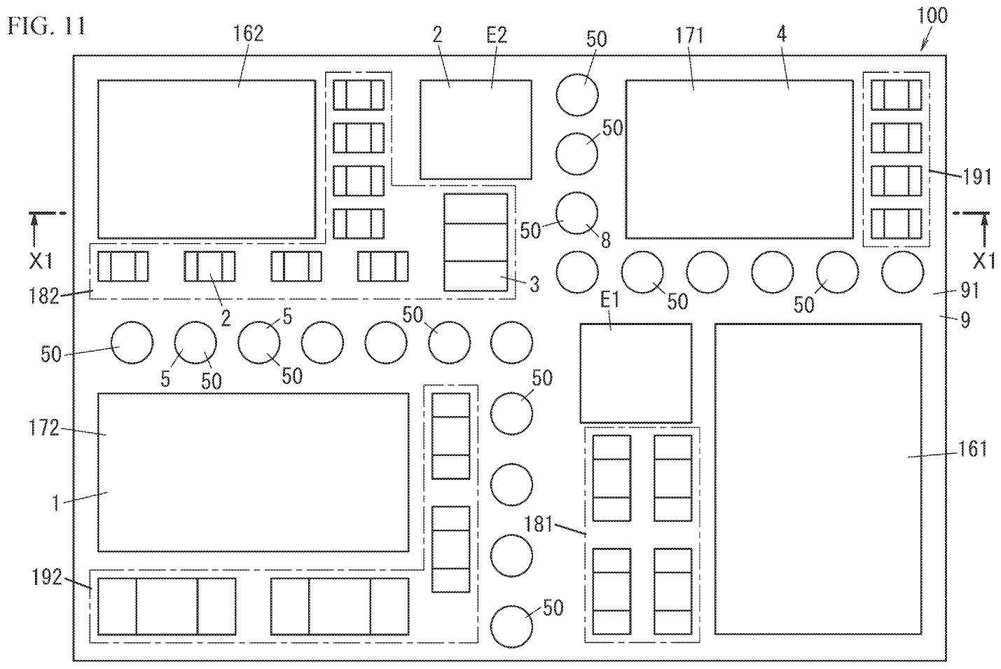

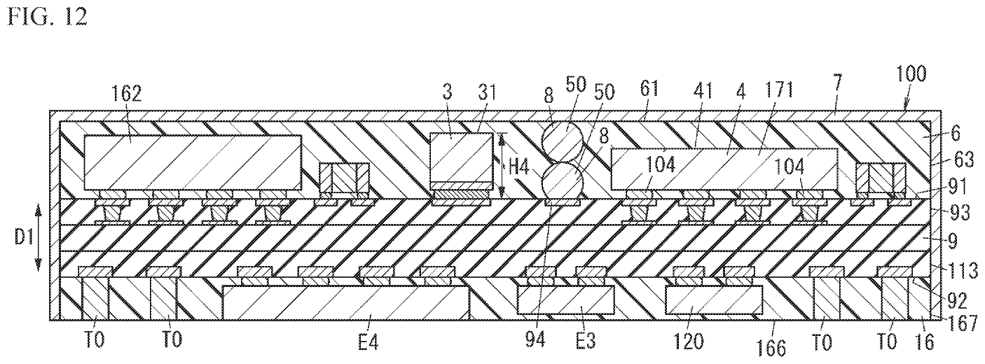

A high frequency module 100 according to Embodiment 7 will be described with reference to FIGS. 11 and 12. Regarding the high frequency module 100 according to Embodiment 7, the same components as the high frequency module 100 (see FIGS. 1 to 4) according to Embodiment 1 are attached with the same reference numerals, and the description thereof will be omitted. In FIG. 11, the first resin layer 6 (see FIG. 12) and the outer shield electrode 7 (see FIG. 12) are not shown.

The high frequency module 100 according to Embodiment 7 includes a third electronic component 3 and a fourth electronic component 4. The third electronic component 3 and the fourth electronic component 4 are disposed on the main surface 91 of the mounting board 9. In the high frequency module 100 according to Embodiment 7, the power amplifier 172 is an example of the first electronic component 1, and one circuit element among the plurality of circuit elements of the input matching circuit 182 is an example of the second electronic component 2. Further, in the high frequency module 100 according to Embodiment 7, one circuit element among the plurality of circuit elements of the input matching circuit 182 is an example of the third electronic component 3, and the power amplifier 171 is an example of the fourth electronic component 4.

Further, the high frequency module 100 according to Embodiment 7 further includes a connection shield member 8. The connection shield member 8 is disposed between the third electronic component 3 and the fourth electronic component 4 on the main surface 91 of the mounting board 9. A fourth height H4, which is from the main surface 91 of the mounting board 9 to a top surface 31 of the third electronic component 3, is higher than the second height H2 (see FIG. 1), which is from the main surface 91 of the mounting board 9 to the top surface 11 of the first electronic component 1, and the third height H3 (see FIG. 1), which is from the main surface 91 of the mounting board 9 to the top surface 21 of the second electronic component 2. The connection shield member 8 is connected to the outer shield electrode 7. The connection shield member 8, for example, the shield member 5 includes two solder bumps 50 stacked in the thickness direction D1 of the mounting board 9.

As with the high frequency module 100 according to Embodiment 2, since the high frequency module 100 according to Embodiment 6 has the first height H1 lower than at least one of the second height H2 and the third height H3, it is possible to achieve size reduction.

Further, since the high frequency module 100 according to Embodiment 6 includes the connection shield member 8, and the connection shield member 8 is connected to the outer shield electrode 7, it is possible to further improve shielding performance.

### Embodiment 8

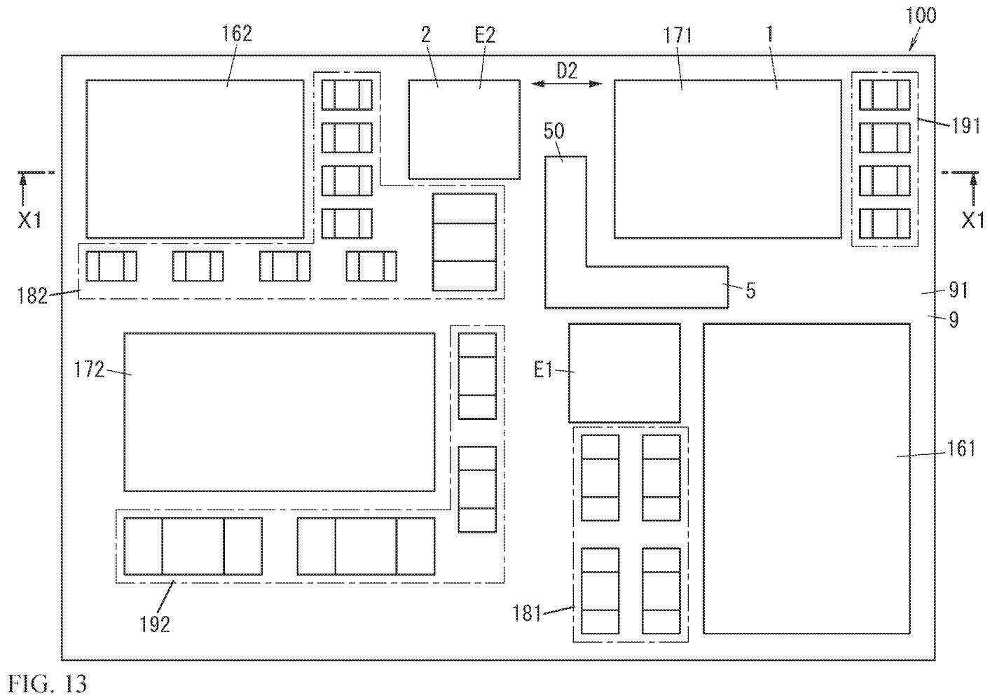

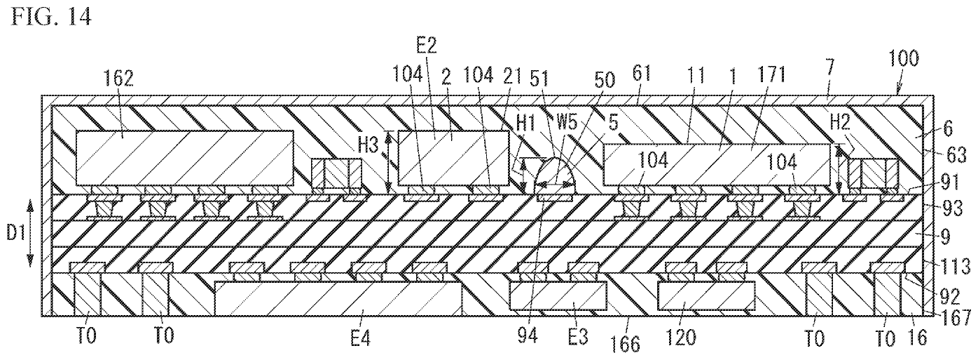

A high frequency module 100 according to Embodiment 8 will be described with reference to FIGS. 13 and 14. Regarding the high frequency module 100 according to Embodiment 8, the same components as the high frequency module 100 (see FIGS. 1 to 4) according to Embodiment 1 are attached with the same reference numerals, and the description thereof will be omitted. In FIG. 13, the first resin layer 6 (see FIG. 14) and the outer shield electrode 7 (see FIG. 14) are not shown.

The high frequency module 100 according to Embodiment 8 is different from the high frequency module 100 according to Embodiment 1 in a fact that the shield member 5 has an L shape in a plan view from the thickness direction D1 of the mounting board 9. The shield member 5 is a solder bump. In Embodiment 8, the L-shaped shield member 5 is disposed along two adjacent sides in the four sides included in the outer edge of the first electronic component 1. In the high frequency module 100 according to Embodiment 8, the first electronic component 1 and the second electronic component 2 are arranged in a second direction D2 orthogonal to the thickness direction D1 (hereinafter, also referred to as a first direction D1) of the mounting board 9. The shield member 5 has a first height H1 that is longer than a width W5 in the second direction D2.

As with the high frequency module 100 according to Embodiment 1, since the high frequency module 100 according to Embodiment 8 has the first height H1 lower than at least one of the second height H2 and the third height H3, it is possible to achieve size reduction.

In the high frequency module 100 according to Embodiment 8, as compared with Embodiment 1, the width of the shield member 5 can be made narrow in the second direction D2, and each of a distance between the shield member 5 and the first electronic component 1 and a distance between the shield member 5 and the second electronic component 2 can be shortened, and then it is possible to achieve further size reduction.

In Embodiment 8, although the shield member 5 has an L shape disposed along two adjacent sides in the four sides included in the outer edge of the first electronic component 1 in a plan view from the thickness direction D1 of the mounting board 9, the shield member 5 is not limited to have an L shape and may have a U shape disposed along three sides in the four sides.

### Embodiment 9

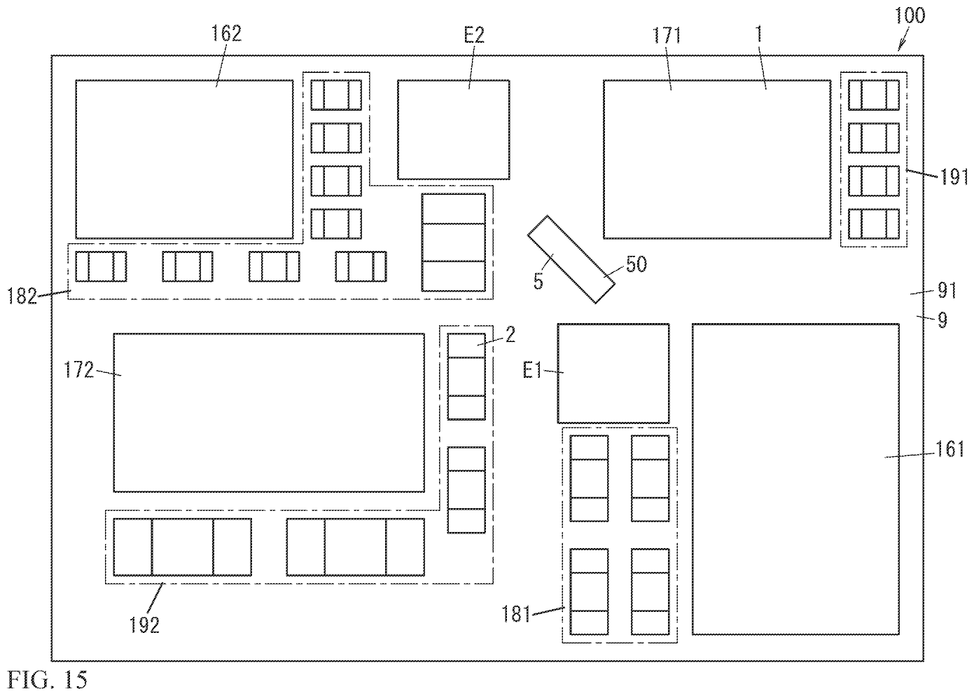

A high frequency module 100 according to Embodiment 9 will be described with reference to FIG. 15. Regarding the high frequency module 100 according to Embodiment 9, the same components as the high frequency module 100 (see FIGS. 1 to 4) according to Embodiment 1 are attached with the same reference numerals, and the description thereof will be omitted. In FIG. 15, the first resin layer 6 (see FIG. 1) and the outer shield electrode 7 (see FIG. 2) are not shown.

The high frequency module 100 according to Embodiment 9 is different from the high frequency module 100 according to Embodiment 1 in a fact that the first electronic component 1 is the power amplifier 171, and the second electronic component 2 is one of the plurality of circuit elements of the output matching circuit 192. Further, the high frequency module 100 according to Embodiment 9 is different from the high frequency module 100 according to Embodiment 1 in a fact that the shield member 5 has an oblong shape. The shield member 5 is a solder bump. The shield member 5 is disposed such that a longitudinal direction of the shield member 5 intersects a direction in which the first electronic component 1 and the second electronic component 2 are arranged, in a plan view from the thickness direction D1 of the mounting board 9.

As with the high frequency module 100 according to Embodiment 1, since the high frequency module 100 according to Embodiment 9 has the first height H1 lower than at least one of the second height H2 and the third height H3, it is possible to achieve size reduction.

### Embodiment 10

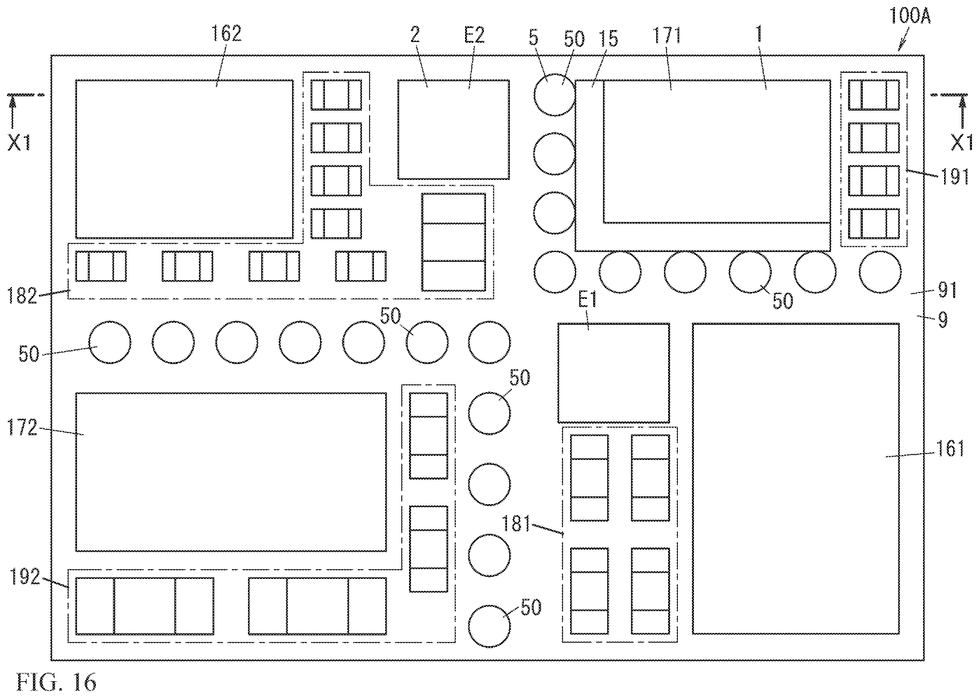

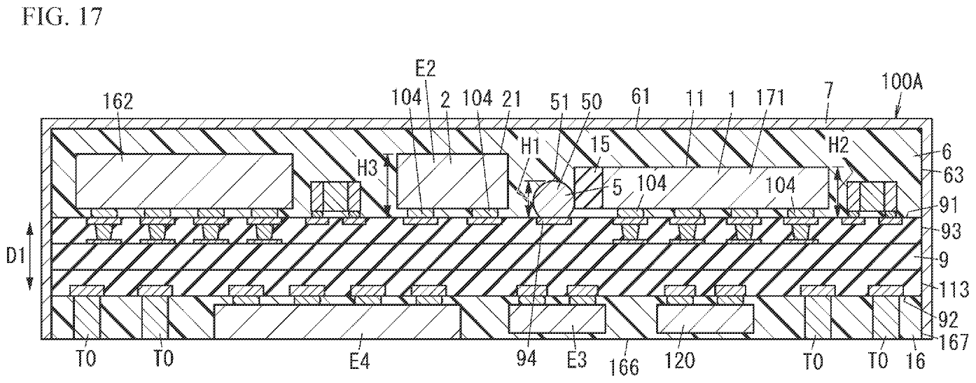

A high frequency module 100A according to Embodiment 10 will be described with reference to FIGS. 16 and 17. Regarding the high frequency module 100A according to Embodiment 10, the same components as the high frequency module 100 (see FIGS. 1 to 4) according to Embodiment 1 are attached with the same reference numerals, and the description thereof will be omitted.

The high frequency module 100A according to Embodiment 10 is different from the high frequency module 100 according to Embodiment 1 in a fact that the high frequency module 100A further includes a heat dissipation member 15. The heat dissipation member 15 includes a portion interposed between the first electronic component 1 and the shield member 5. In Embodiment 10, in a plan view from the thickness direction D1 of the mounting board 9, the heat dissipation member 15 has an L shape and is in contact with two adjacent side surfaces in four side surfaces of the first electronic component 1. Further, the heat dissipation member 15 is in contact with the plurality of solder bumps 50 facing the two side surfaces of the first electronic component 1. The heat dissipation member 15 may be formed on at least a part of the top surface 11 of the first electronic component 1.

The heat dissipation member 15 has thermal conductivity and electric insulation. The material of the heat dissipation member 15 includes, for example, a thermal interface material (TIM). The heat dissipation member 15 is a thermal conduction sheet. The thermal conduction sheet is, for example, a sheet-like member containing a resin and a filler filled in the resin. The filler contains, for example, aluminum nitride, boron nitride, carbon nanotubes, or graphene. The heat dissipation member 15 is not limited to a thermal conduction sheet, and may be, for example, thermal conduction grease.

As with the high frequency module 100 according to Embodiment 1, since the high frequency module 100A according to Embodiment 10 has the first height H1 lower than at least one of the second height H2 and the third height H3, it is possible to achieve size reduction.

Further, since the high frequency module 100A according to Embodiment 10 includes the heat dissipation member 15, it is possible to improve heat dissipation performance, and it is possible to suppress a rise in temperature of the first electronic component 1.

### Embodiment 11

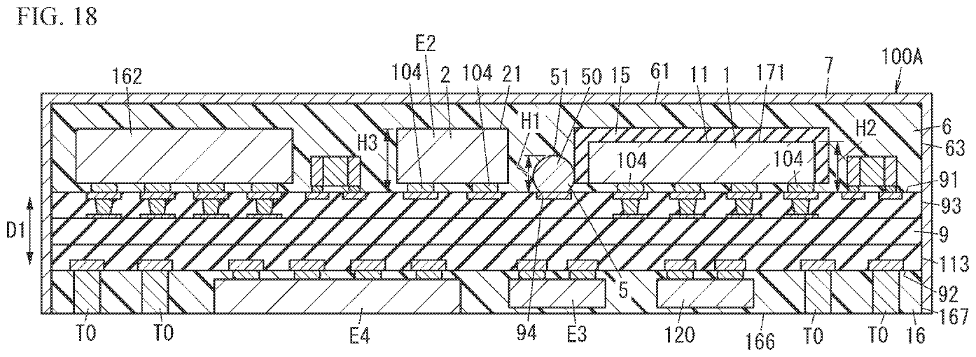

A high frequency module 100A according to Embodiment 11 will be described with reference to FIG. 18. Regarding the high frequency module 100A according to Embodiment 11, the same components as the high frequency module 100A (see FIGS. 16 and 17) according to Embodiment 10 are attached with the same reference numerals, and the description thereof will be omitted.

The high frequency module 100A according to Embodiment 11 is different from the high frequency module 100A according to Embodiment 10 in a fact that the heat dissipation member 15 covers the top surface 11 and four side surfaces of the first electronic component 1.

As with the high frequency module 100 according to Embodiment 10, since the high frequency module 100A according to Embodiment 11 has the first height H1 lower than at least one of the second height H2 and the third height H3, it is possible to achieve size reduction.

Further, in the high frequency module 100A according to Embodiment 11, since the heat dissipation member 15 covers the top surface 11 and the four side surfaces of the first electronic component 1, it is possible to improve the heat dissipation performance as compared with the high frequency module 100 according to Embodiment 10.

### Embodiment 12

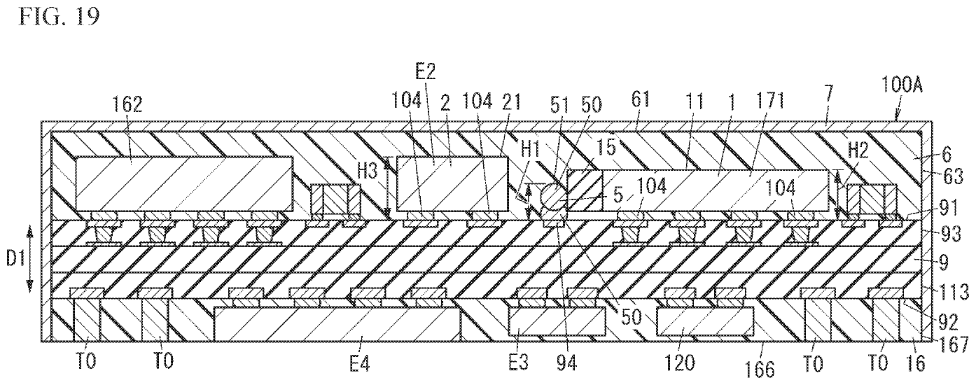

A high frequency module 100A according to Embodiment 12 will be described with reference to FIG. 19. Regarding the high frequency module 100A according to Embodiment 12, the same components as the high frequency module 100A (see FIGS. 16 and 17) according to Embodiment 10 are attached with the same reference numerals, and the description thereof will be omitted.

In the high frequency module 100A according to Embodiment 12, a shape of the shield member 5 is different from the shape of the shield member 5 of the high frequency module 100A according to Embodiment 10. In the high frequency module 100A according to Embodiment 12, the shield member 5 includes two solder bumps 50 stacked in the thickness direction D1 of the mounting board 9.

As with the high frequency module 100 according to Embodiment 10, since the high frequency module 100A according to Embodiment 12 has the first height H1 lower than at least one of the second height H2 and the third height H3, it is possible to achieve size reduction.

In the high frequency module 100A according to Embodiment 12, since the two solder bumps 50 are stacked on the shield member 5, the size of the solder bumps 50 can be made smaller as compared with Embodiment 10, and each of a distance between the shield member 5 and the first electronic component 1 and a distance with the second electronic component 2 can be shortened, and then it is possible to achieve further size reduction.

### Embodiment 13

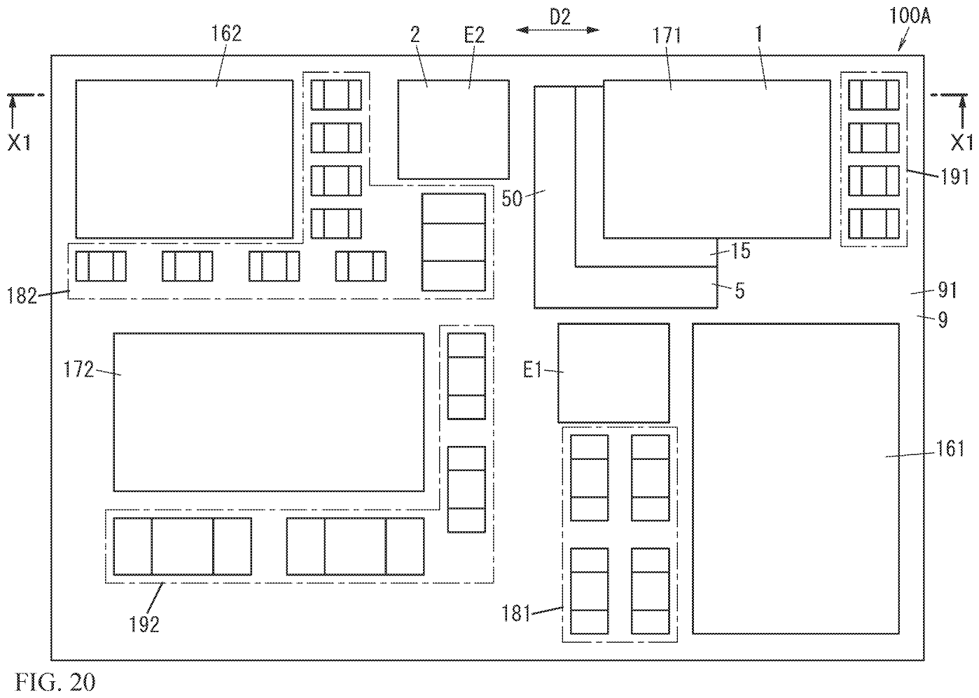

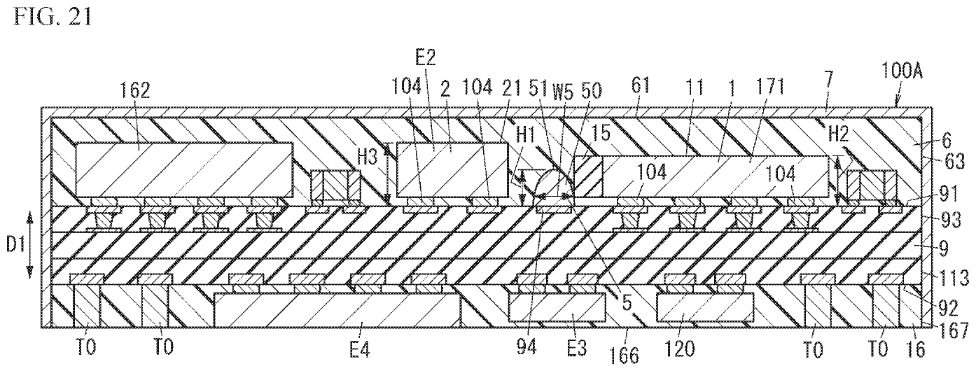

A high frequency module 100A according to Embodiment 13 will be described with reference to FIGS. 20 and 21. Regarding the high frequency module 100A according to Embodiment 13, the same components as the high frequency module 100A (see FIGS. 16 and 17) according to Embodiment 10 are attached with the same reference numerals, and the description thereof will be omitted.

The high frequency module 100A according to Embodiment 13 is different from the high frequency module 100A according to Embodiment 10 in a fact that the shield member 5 has an L shape in a plan view from the thickness direction D1 of the mounting board 9. The shield member 5 is a solder bump. In Embodiment 13, the L-shaped shield member 5 is disposed along two adjacent sides in the four sides included in the outer edge of the first electronic component 1. In Embodiment 13, the L-shaped heat dissipation member 15 is interposed between the L-shaped shield member 5 and the two side surfaces of the first electronic component 1.

In the high frequency module 100A according to Embodiment 13, the first electronic component 1 and the second electronic component 2 are arranged in a second direction D2 orthogonal to the thickness direction D1 (hereinafter, also referred to as a first direction D1) of the mounting board 9. The shield member 5 has a first height H1 that is longer than a width W5 in the second direction D2.

As with the high frequency module 100A according to Embodiment 10, since the high frequency module 100A according to Embodiment 13 has the first height H1 lower than at least one of the second height H2 and the third height H3, it is possible to achieve size reduction.

Further, in the high frequency module 100A according to Embodiment 13, since the shield member 5 has an L shape, it is possible to improve the heat dissipation performance as compared with that of Embodiment 10.

Embodiments 1 to 13 or the like described above are merely one of various embodiments of the present disclosure. Various modifications to Embodiments 1 to 13 or the like described above are possible according to the design or the like as long as the possible benefit of the present disclosure can be achieved.

For example, each of a plurality of acoustic wave resonators included in the acoustic wave filter is not limited to a SAW resonator and may be a bulk acoustic wave (BAW) resonator. In this case, for example, the board 10 of the second electronic component 2 may be, for example, a spinel board or a board including a silicon board and an insulation film formed on the silicon board.

Further, each of the plurality of external connection terminals TO is not limited to a columnar electrode and may be, for example, a ball bump.

Further, the plurality of external connection terminals TO are not components of the mounting board 9 and may be components of the mounting board 9.

Further, the communication device 300 may include the high frequency module 100 according to any one of Embodiments 2 to 9 or the high frequency module 100A according to any one of Embodiments 10 to 13, instead of the high frequency module 100 according to Embodiment 1.

### Aspects

The following aspects are disclosed in the present specification.

A high frequency module (100; 100A) according to a first aspect includes a mounting board (9), a first electronic component (1), a second electronic component (2), and a shield member (5). The mounting board (9) has a main surface (91). The first electronic component (1) and the second electronic component (2) are disposed on the main surface (91) of the mounting board (9). The shield member (5) is disposed on the main surface (91) of the mounting board (9). The shield member (5) is positioned between the first electronic component (1) and the second electronic component (2) and is adjacent to the first electronic component (1) and the second electronic component (2). A first height (H1), which is from the main surface (91) of the mounting board (9) to a top portion (51) of the shield member (5), is lower than at least one of a second height (H2), which is from the main surface (91) of the mounting board (9) to a top surface (11) of the first electronic component (1), and a third height (H3), which is from the main surface (91) of the mounting board (9) to a top surface (21) of the second electronic component (2).

According to the aspect, it is possible to achieve size reduction.

In the high frequency module (100; 100A) according to a second aspect, in the first aspect, the first height (H1) is lower than both the second height (H2) and the third height (H3).

According to the aspect, it is possible to achieve further size reduction.

In the high frequency module (100; 100A) according to a third aspect, in the first or second aspect, at least one of the first electronic component (1) and the second electronic component (2) includes a board (10), a circuit portion (103), and a plurality of bump electrodes (104). The board (10) has a first main surface (101) and a second main surface (102) opposite to each other. The circuit portion (103) is formed on the first main surface (101) of the board (10). The plurality of bump electrodes (104) are connected to the circuit portion (103). At least one of the first electronic component (1) and the second electronic component (2) is connected to the mounting board (9) through the plurality of bump electrodes (104). The first height (H1) is higher than a height (H5), which is from the main surface (91) of the mounting board (9) to the first main surface (101) of the board (10).

According to the aspect, it is possible to achieve size reduction while improving the isolation between the circuit portion (103) of the first electronic component (1) and the circuit portion (103) of the second electronic component (2).

In the high frequency module (100; 100A) according to a fourth aspect, in any one of the first to third aspects, the first electronic component (1) is a transmission electronic component, and the second electronic component (2) is a reception electronic component.

According to the aspect, it is possible to achieve size reduction while improving the isolation between the transmission electronic component, which is the first electronic component (1), and the reception electronic component, which is the second electronic component (2).

In the high frequency module (100; 100A) according to a fifth aspect, in the fourth aspect, the transmission electronic component includes a power amplifier (171).

In the high frequency module (100; 100A) according to a sixth aspect, in any one of the fourth or fifth aspect, the reception electronic component includes a low noise amplifier (163, 164).

In the high frequency module (100; 100A) according to a seventh aspect, in any one of the first to sixth aspects, the mounting board (9) has a fourth main surface (92) opposite to a third main surface (91), which is the main surface (91). The mounting board (9) includes a land electrode (94), a ground electrode (95), and a via conductor (96). The shield member (5) is disposed on the land electrode (94). The ground electrode (95) is disposed between the land electrode (94) and the fourth main surface (92) in a thickness direction (D1) of the mounting board (9) to be spaced apart from the land electrode (94) and the fourth main surface (92). The via conductor (96) connects the land electrode (94) and the ground electrode (95).

According to the aspect, it is possible to suppress the expansion of the magnetic field generated by at least one of the first electronic component (1) and the second electronic component (2) in the mounting board (9).

In the high frequency module (100; 100A) according to an eighth aspect, in the seventh aspect, a plurality of the shield members (5) and a plurality of the land electrodes (94) are further included.

According to the aspect, the shielding performance can be further improved.

In the high frequency module (100; 100A) according to a ninth aspect, in the eighth aspect, the mounting board (9) includes a conductor portion (98) and a resist layer (97). The conductor portion (98) includes at least two land electrodes (94) among the plurality of land electrodes (94). A resist layer (97) is provided on the conductor portion (98) and includes at least two cavities (971). The at least two land electrodes (94) are portions that correspond to the at least two cavities (971) in a one-to-one manner and that are exposed through the at least two cavities (971) in the conductor portion (98). The via conductor (96) is common to the at least two land electrodes (94), and connects the conductor portion (98) to the ground electrode (95).

According to the aspect, the degree of freedom in wiring layout in the mounting board (9) is increased while improving the shielding performance.

In the high frequency module (100; 100A) according to a tenth aspect is, in any one of the first to ninth aspects, a resin layer (6) and an outer shield electrode (7) are further included. The resin layer (6) is disposed on the main surface (91) of the mounting board (9). The resin layer (6) covers at least a part of the first electronic component (1) and at least a part of the second electronic component (2). The outer shield electrode (7) covers the resin layer (6).

According to the aspect, it is possible to improve the shielding performance against each of electromagnetic wave noise from the outside of the high frequency module (100; 100A), and electromagnetic wave noise from the high frequency module (100) to the outside.

In the high frequency module (100; 100A) according to an eleventh aspect, in the tenth aspect, a third electronic component (3), a fourth electronic component (4), and a connection shield member (8) are further included. The third electronic component (3) and the fourth electronic component (4) are disposed on the main surface (91) of the mounting board (9). The connection shield member (8) is disposed between the third electronic component (3) and the fourth electronic component (4) on the main surface (91) of the mounting board (9). The fourth height (H4), which is from the main surface (91) of the mounting board (9) to a top surface (31) of the third electronic component (3), is higher than the second height (H2) and the third height (H3). The connection shield member (8) is connected to the outer shield electrode (7).

According to the aspect, it is possible to further improve the shielding performance.

In the high frequency module (100; 100A) according to a twelfth aspect, in any one of the first to seventh aspects, outer edges of each of the first electronic component (1) and the second electronic component (2) have a rectangular shape in a plan view from a thickness direction (D1) of the mounting board (9). The shield member (5) has an L shape along two adjacent sides of the first electronic component (1) or the second electronic component (2), in a plan view from the thickness direction (D1) of the mounting board (9).

According to the aspect, it is possible to improve the shielding performance.

In the high frequency module (100A) according to a thirteenth aspect, in any one of the first to twelfth aspects, a heat dissipation member (15) is further included. The heat dissipation member (15) includes a portion interposed between the first electronic component (1) and the shield member (5).

According to the aspect, it is possible to improve the heat dissipation performance.

In the high frequency module (100; 100A) according to a fourteenth aspect, in any one of the first to thirteenth aspects, the shield member (5) includes a solder bump.

According to this aspect, the shield member (5) can be easily formed by using a printing method or the like.

A communication device (300) according to a fifteenth aspect includes the high frequency module (100; 100A) according to any one of the first to fourteenth aspects, and a signal processing circuit (301). The signal processing circuit (301) is connected to the high frequency module (100).

According to the aspect, it is possible to achieve size reduction.

What is claimed is:

1. A high frequency module comprising:
a mounting board having a main surface;
a first electronic component and a second electronic component disposed on the main surface of the mounting board; and
at least one shield member disposed on the main surface of the mounting board, wherein
the shield member is positioned between the first electronic component and the second electronic component, and is adjacent to the first electronic component and the second electronic component, and
a first height from the main surface of the mounting board to a top portion of the shield member is lower than at least one of a second height from the main surface of the mounting board to a top surface of the first electronic component, and a third height from the main surface of the mounting board to a top surface of the second electronic component.

2. The high frequency module according to claim 1, wherein
the first height is lower than both the second height and the third height.

3. The high frequency module according to claim 1, wherein
at least one of the first electronic component and the second electronic component
includes a board having a first main surface and a second main surface opposite to each other,
a circuit portion provided on the first main surface of the board, and
a plurality of bump electrodes connected to the circuit portion, and
is connected to the mounting board through the plurality of bump electrodes, and
the first height is higher than a height from the main surface of the mounting board to the first main surface of the board.

4. The high frequency module according to claim 1, wherein
the first electronic component is a transmission electronic component, and
the second electronic component is a reception electronic component.

5. The high frequency module according to claim 4, wherein
the transmission electronic component includes a power amplifier.

6. The high frequency module according to claim 4, wherein
the reception electronic component includes a low noise amplifier.

7. The high frequency module according to claim 1, wherein
the mounting board has a fourth main surface opposite to a third main surface being the main surface, and
the mounting board includes
at least one land electrode having the shield member disposed,
a ground electrode disposed between the land electrode and the fourth main surface in a thickness direction of the mounting board to be spaced apart from the land electrode and the fourth main surface, and
a via conductor connecting the land electrode and the ground electrode.

8. The high frequency module according to claim 7, wherein
the at least one shield member comprises a plurality of shield members; and
the at least one land electrode comprises a plurality of land electrodes.

9. The high frequency module according to claim 8, wherein
the mounting board includes
a conductor portion including at least two land electrodes among the plurality of land electrodes, and
a resist layer provided on the conductor portion and including at least two cavities,
the at least two land electrodes are portions corresponding to the at least two cavities in a one-to-one manner and exposed through the at least two cavities in the conductor portion, and
the via conductor is common to the at least two land electrodes and connects the conductor portion and the ground electrode.

10. The high frequency module according to claim 1, further comprising:
a resin layer disposed on the main surface of the mounting board and covering at least a part of the first electronic component and at least a part of the second electronic component; and
an outer shield electrode covering the resin layer.

11. The high frequency module according to claim 10, further comprising:
a third electronic component and a fourth electronic component disposed on the main surface of the mounting board; and
a connection shield member disposed between the third electronic component and the fourth electronic component on the main surface of the mounting board, wherein
a fourth height from the main surface of the mounting board to a top surface of the third electronic component is higher than the second height and the third height, and
the connection shield member is connected to the outer shield electrode.

12. The high frequency module according to claim 1, wherein
an outer edge of each of the first electronic component and the second electronic component has a rectangular shape in a plan view from a thickness direction of the mounting board, and
the shield member has an L shape along two adjacent sides of the first electronic component or the second electronic component, in a plan view from the thickness direction of the mounting board.

13. The high frequency module according to claim 1, further comprising:
a heat dissipation member including a portion interposed between the first electronic component and the shield member.

14. The high frequency module according to claim 1, wherein
the shield member includes a solder bump.

15. A communication device comprising:
the high frequency module according to claim 1; and
a signal processing circuit connected to the high frequency module.

16. The high frequency module according to claim 2, wherein
at least one of the first electronic component and the second electronic component
includes a board having a first main surface and a second main surface opposite to each other,
a circuit portion provided on the first main surface of the board, and
a plurality of bump electrodes connected to the circuit portion, and
is connected to the mounting board through the plurality of bump electrodes, and
the first height is higher than a height from the main surface of the mounting board to the first main surface of the board.

17. The high frequency module according to claim 2, wherein
the first electronic component is a transmission electronic component, and
the second electronic component is a reception electronic component.

18. The high frequency module according to claim 2, wherein
the mounting board has a fourth main surface opposite to a third main surface being the main surface, and
the mounting board includes
at least one land electrode having the shield member disposed,
a ground electrode disposed between the land electrode and the fourth main surface in a thickness direction of the mounting board to be spaced apart from the land electrode and the fourth main surface, and
a via conductor connecting the land electrode and the ground electrode.

19. The high frequency module according to claim 2, further comprising:
a resin layer disposed on the main surface of the mounting board and covering at least a part of the first electronic component and at least a part of the second electronic component; and
an outer shield electrode covering the resin layer.

20. The high frequency module according to claim 2, wherein
an outer edge of each of the first electronic component and the second electronic component has a rectangular shape in a plan view from a thickness direction of the mounting board, and
the shield member has an L shape along two adjacent sides of the first electronic component or the second electronic component, in a plan view from the thickness direction of the mounting board.
